(19) United States
(12) Patent Application Publication
(10) Pub. No.: US 2025/0130282 A1
(43) Pub. Date: Apr. 24, 2025

(54) Battery Measurement Device

(71) Applicant: SK On Co., Ltd., Seoul (KR)

(72) Inventors: Chang Mook HWANG, Daejeon (KR); Chul Ho KANG, Daejeon (KR); Myeong Seon KWON, Daejeon (KR); Mi So RHO, Daejeon (KR)

(21) Appl. No.: 18/916,894

(22) Filed: Oct. 16, 2024

(30) Foreign Application Priority Data
Oct. 19, 2023 (KR) 10-2023-0140000

(51) Int. Cl. G01R 31/3835

(52) U.S. Cl. CPC G01R 31/3835

(57) ABSTRACT

A battery measurement device of the present disclosure includes a first electrode contact terminal contacted with a first electrode of a battery to measure the voltage of the battery; and a second electrode contact terminal contacted with a second electrode of the battery to measure the voltage. At least one of the first electrode contact terminal and the second electrode contact terminal includes: a first protruding portion protruding from a reference position to a first length to be contacted with an opposing electrode; and a second protruding portion protruding from the reference position to a second length to be contacted with the opposing electrode when the first protruding portion is worn.

### CROSS-REFERENCE TO RELATED PATENT APPLICATION

The present application claims priority under 35 U.S.C. § 119(a) to Korean patent application number 10-2023-0140000 filed on Oct. 19, 2023, in the Korean Intellectual Property Office, the entire disclosure of which is incorporated by reference herein.

### BACKGROUND OF THE INVENTION

### 1. Field

The present disclosure relates to an electronic device, and specifically to a battery measurement device.

### 2. Description of the Related Art

Batteries undergo a formation process during the manufacturing process. The formation process refers to a process of repeatedly charging and discharging an initially discharged battery several times to give electrical characteristics to the battery and testing its discharge capacity.

In this case, the voltage of the battery may be measured using a battery measurement device. To this end, a battery measurement device may be electrically connected to a battery through inter-conductor contact. On the other hand, there is a problem that the contact terminals of battery measurement devices are worn or deteriorated depending on the number of contacts with batteries, making measurement impossible or inaccurate even when measurement is possible. Measures to prevent this problem are being explored.

### SUMMARY OF THE INVENTION

An object of the present disclosure is to measure a battery measurement device with an extended service life.

The present disclosure can be widely applied in the field of green technology such as solar power generation and wind power generation. In addition, the present disclosure can be used in eco-friendly devices such as electric vehicles and hybrid vehicles prevent climate change by suppressing air pollution and greenhouse gas emissions.

A battery measurement device according to an embodiment includes: a first electrode contact terminal contacted with a first electrode of a battery to measure the voltage of the battery; and a second electrode contact terminal contacted with a second electrode of the battery to measure the voltage. At least one of the first electrode contact terminal and the second electrode contact terminal includes: a first protruding portion protruding from a reference position to a first length to be contacted with an opposing electrode among the first electrode and the second electrode; and a second protruding portion protruding from the reference position to a second length to be contacted with the opposing electrode when the first protruding portion is worn.

In an embodiment, when the first length is formed to be longer than the second length, the first protruding portion may be contacted with the opposing electrode.

In an embodiment, the battery measurement device may further include a sensing circuit measuring the voltage of the battery through the first protruding portion while the first protruding portion is contacted with the opposing electrode.

In an embodiment, the difference between the first length and the second length before the first protruding portion may be worn is 500 μm or more.

In an embodiment, when the first protruding portion is worn and the first length is formed to be less than or equal to the second length, the second protruding portion may be contacted with the opposing electrode.

In an embodiment, the battery measurement device may further include a sensing circuit measuring the voltage of the battery through the second protruding portion while the second protruding portion is contacted with the opposing electrode.

In an embodiment, at least one of the first electrode contact terminal and the second electrode contact terminal may include a third protruding portion protruding from the reference position to a third length to be contacted with the opposing electrode when the first protruding portion and the second protruding portion are worn.

In an embodiment, when the first protruding portion and the second protruding portion are worn and the first length and the second length are formed to be less than or equal to the third length, the third protruding portion may be contacted with the opposing electrode.

In an embodiment, the battery measurement device may further include a sensing circuit measuring the voltage of the battery through the third protruding portion while the third protruding portion is contacted with the opposing electrode.

In an embodiment, the difference between the second length and the third length before the second protruding portion is worn may be 500 μm or more.

The present disclosure can provide a battery measurement device with an extended service life.

According to an embodiment of the present disclosure, the service life of the battery measurement device can be extended step by step.

According to an embodiment of the present disclosure, the voltage of a battery can be accurately measured.

### BRIEF DESCRIPTION OF THE DRAWINGS

FIG. 1 shows a diagram for explaining a battery measurement device according to an embodiment.

FIG. 2 shows a diagram for explaining a protruding portion according to an embodiment.

FIG. 3 shows a diagram for explaining a state in which a first protruding portion according to an embodiment is worn.

FIG. 4 shows a diagram for explaining a state in which a first protruding portion and a second protruding portion according to an embodiment are worn.

### DETAILED DESCRIPTION

The structural or functional descriptions of embodiments disclosed in the present specification or application are merely illustrated for the purpose of explaining embodiments according to the technical principle of the present invention, and embodiments according to the technical principle of the present invention may be implemented in various forms in addition to the embodiments disclosed in the present specification or application. In addition, the technical principle of the present invention is not construed as being limited to the embodiments described in the present specification or application.

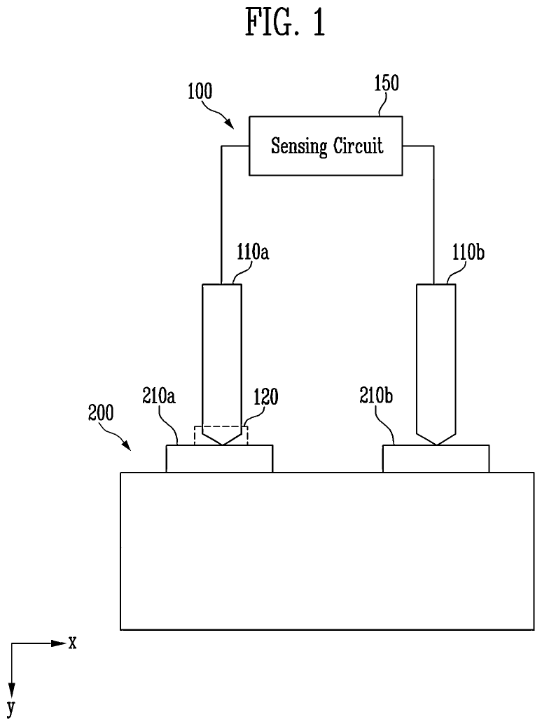

FIG. 1 shows a diagram for explaining a battery measurement device according to an embodiment.

In an embodiment, the battery measurement device according to an embodiment includes: a first electrode contact terminal contacted with a first electrode of a battery to measure the voltage of the battery; and a second electrode contact terminal contacted with a second electrode of the battery to measure the voltage. At least one of the first electrode contact terminal and the second electrode contact terminal includes: a first protruding portion protruding from a reference position to a first length to be contacted with an opposing electrode among the first electrode and the second electrode; and a second protruding portion protruding from the reference position to a second length to be contacted with the opposing electrode when the first protruding portion is worn.

Referring to FIG. 1, the battery measurement device 100 may measure the voltage of a battery 200. For example, the battery measurement device 100 may measure the voltage of a battery 200 while the battery 200 is undergoing a formation process.

A battery 200 may be a secondary battery. In an embodiment, a battery 200 may include an electrode assembly and an electrolyte. For example, an electrode assembly may include a cathode and an anode. In an embodiment, an electrode assembly may further include a separator preventing contact between a cathode and an anode. In an embodiment, a battery 200 may further include an exterior material. For example, an exterior material may be implemented to have materials and shapes according to various types such as pouch type, prismatic type, and cylindrical type.

A battery 200 may include a first electrode 210a and a second electrode 210b. A first electrode 210a and a second electrode 210b may be electrode tabs having different polarities. For example, a first electrode 210a may be a cathode tab electrically connected to a cathode, and a second electrode 210b may be an anode tab electrically connected to an anode. For another example, a first electrode 210a may be an anode tab, and a second electrode 210b may be a cathode tab. To this end, each of a first electrode 210a and a second electrode 210b may include a conductor.

A first electrode 210a and a second electrode 210b may each protrude in one direction to be electrically connected to an external device. In an embodiment, the protruding directions of a first electrode 210a and a second electrode 210b may be the same. For example, referring to FIG. 1, a first electrode 210a and a second electrode 210b may each protrude in the-Y-axis direction. However, this is only an example, and the protruding directions of a first electrode 210a and a second electrode 210b may be modified to be different from each other.

In an embodiment, a battery measurement device 100 may include a first electrode contact terminal 110a and a second electrode contact terminal 110b for measuring the voltage of a battery 200. A first electrode contact terminal 110a may be contacted with a first electrode 210a of a battery 200. A second electrode contact terminal 110b may be contacted with a second electrode 210b of a battery 200.

In an embodiment, a battery measurement device 100 may further include a sensing circuit 150 electrically connected between a first electrode contact terminal 110a and a second electrode contact terminal 110b. Here, the sensing circuit 150 may be a voltmeter. A sensing circuit 150 may measure the voltage between a first electrode 210a contacted with a first electrode contact terminal 110a and a second electrode 210b contacted with a second electrode contact terminal 110b.

At least one of a first electrode contact terminal 110a and a second electrode contact terminal 110b may include a plurality of protruding portions. In other words, either a first electrode contact terminal 110a or a second electrode contact terminal 110b may include a plurality of protruding portions, or both a first electrode contact terminal 110a and a second electrode contact terminal 110b may include a plurality of protruding portions. One of the plurality of protruding portions may have a different height (or length) from another protruding portion. According to the present disclosure, the service life of a battery measurement device 100 may be extended by using protruding portions with different heights (or lengths) to measure the voltage of a battery 200. In this case, the service life of the battery measurement device 100 may be extended step by step.

Hereinafter, an embodiment of the present disclosure will be described in detail using the case where a plurality of protruding portions are included in a first electrode contact terminal 110a as a representative example.

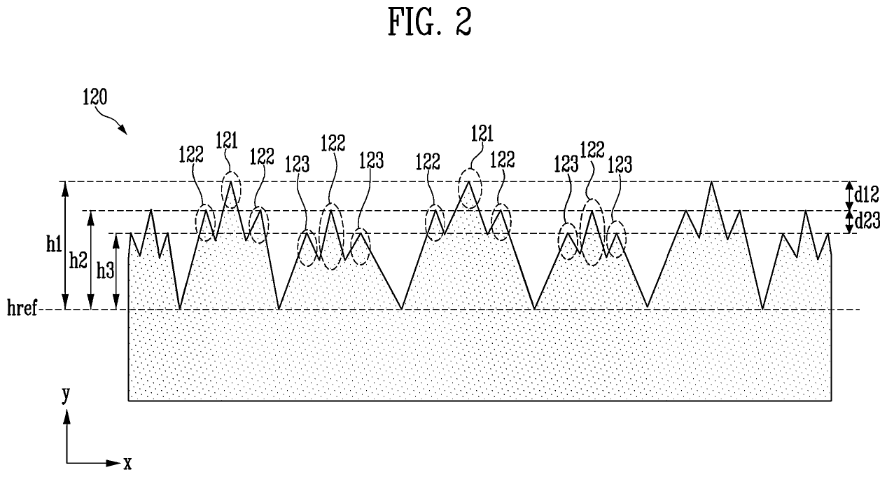

FIG. 2 shows a diagram for explaining a protruding portion according to an embodiment. FIG. 2 shows an enlarged diagram of a contact region 120 of FIG. 1.

Referring to FIGS. 1 and 2, a first electrode contact terminal 110a may include a plurality of protruding portions 121, 122, and 123. A plurality of protruding portions 121, 122, and 123 may protrude in a contact direction. Here, the contact direction may be a direction in which a first electrode contact terminal 110a is contacted with a first electrode 210a. For example, a contact direction may be the Y-axis direction. In an embodiment, each of the plurality of protruding portions 121, 122, and 123 may include a conductor.

In an embodiment, the plurality of protruding portions 121, 122, and 123 may include a first protruding portion 121 and a second protruding portion 122 having different lengths.

A first protruding portion 121 may protrude from a reference position href to a first length h1. A second protruding portion 122 may protrude from a reference position href to a second length h2. Here, the reference position href may be a randomly set reference point. For example, a reference point may be a trough, a crest, or one of a variety of other points. A first length h1 and a second length h2 may be the initial length before a first protruding portion 121 and a second protruding portion 122 are worn. In this case, the first length h1 may be longer than the second length h2. The second protruding portion 122 may be contacted with an opposing electrode when the first protruding portion 121 is worn.

In an embodiment, the difference d12 between a first length h1 and a second length h2 in the initial state before a first protruding portion 121 and a second protruding portion 122 are worn may be greater than or equal to a reference value. For example, a reference value may be 500 μm.

In an embodiment, a plurality of protruding portions 121, 122, and 123 may include a first protruding portion 121, a second protruding portion 122, and a third protruding portion 123 having different lengths. Meanwhile, the number of protruding portions 121, 122, and 123 having different lengths may be modified in various ways.

A first protruding portion 121 may protrude from a reference position href to a first length (h1). A second protruding portion 122 may protrude from a reference position href to a second length h2. A third protruding portion 123 may protrude from a reference position href to a third length h3.

Here, the first length h1, the second length h2, and the third length h3 may be lengths in the initial state before the first protruding portion 121, the second protruding portion 122, and the third protruding portion 123 are worn. In this case, the first length h1 may be longer than the second length h2, and the second length h2 may be longer than the third length h3. A second protruding portion 122 may be contacted with an opposing electrode when a first protruding portion 121 is worn. A third protruding portion 123 may be contacted with an opposing electrode when a first protruding portion 121 and a second protruding portion 122 are worn.

In an embodiment, at least one of the first electrode contact terminal and the second electrode contact terminal may include a third protruding portion protruding from the reference position to a third length to be contacted with the opposing electrode when the first protruding portion and the second protruding portion are worn.

In an embodiment, the difference d23 between a second length h2 and a third length h3 in the initial state before a first protruding portion 121, a second protruding portion 122, and a third protruding portion 123 are worn may be greater than or equal to a reference value. For example, a reference value may be 500 μm.

According to the present disclosure, to measure the voltage of a battery 200, each of a first electrode contact terminal 110a and a second electrode contact terminal 110b of a battery measurement device 100 may be contacted with an opposing electrode of the battery 200. In other words, a first electrode contact terminal 110a may be contacted with a first electrode 210a, and a second electrode contact terminal 110b may be contacted with a second electrode 210b.

Here, at least one of a first electrode contact terminal 110a and a second electrode contact terminal 110b may include a plurality of protruding portions 121, 122, and 123 having different lengths. For example, a first electrode contact terminal 110a may include a plurality of protruding portions 121, 122, and 123 having different lengths. In this case, a first protruding portion 121, which is the longest among the plurality of protruding portions 121, 122, and 123, may be contacted with a first electrode 210a. A first protruding portion 121 may be preferentially worn depending on the usage time or number of contacts with a battery measurement device 100. As the wearing continues, a first length h1 of a first protruding portion 121 may gradually decrease compared to the initial state.

In an embodiment, when a first length h1 of a first protruding portion 121 is formed to be longer than a second length h2 of a second protruding portion 122, among a plurality of protruding portions 121,122, and 123, a first protruding portion 121 may be contacted with an opposing electrode to measure the voltage of a battery 200. In this case, the remaining protruding portions among the plurality of protruding portions 121, 122, and 123 may not be contacted with the electrode. In an embodiment, while a first protruding portion 121 is contacted with an opposing electrode, a sensing circuit 150 may measure the voltage of a battery 200 through the first protruding portion 121.

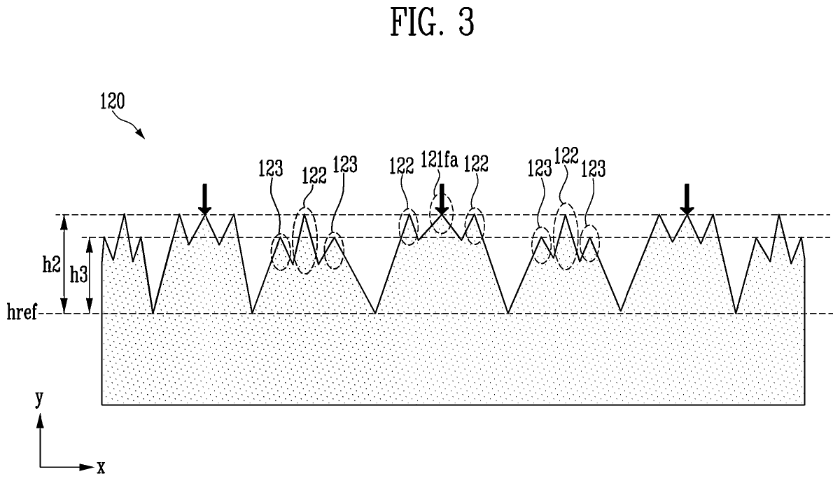

FIG. 3 shows a diagram for explaining a state in which a first protruding portion according to an embodiment is worn. FIG. 3 shows an enlarged diagram of a contact region 120 of FIG. 1.

Referring to FIGS. 1 and 3, in an embodiment, when a first protruding portion 121fa is worn so that a first length of the first protruding portion 121fa become less than or equal to a second length h2 of a second protruding portion 122, the second protruding portion 122 may be contacted with an opposing electrode.

Specifically, as a first protruding portion 121fa is worn depending on the usage time or number of contacts with a battery measurement device 100, a first length of the first protruding portion 121fa may become less than or equal to a second length h2 of a second protruding portion 122. In a state where a first length of a first protruding portion 121fa has become less than or equal to a second length of a second protruding portion 122, a first electrode contact terminal 110a may be contacted with a first electrode 210a to measure the voltage of a battery 200. In this case, among the protruding portions 121fa, 122, and 123 included in the first electrode contact terminal 110a, the second protruding portion 122 may be contacted with the first electrode 210a. Meanwhile, in this case, the first protruding portion 121fa may be contacted with the first electrode 210a, but the contact resistance of the first protruding portion 121fa may increase compared to the initial state as the surface of the first protruding portion 121fa is worn. In this case, voltage measurement through the first protruding portion 121fa may be invalid.

In an embodiment, while a second protruding portion 122 is contacted with an opposing electrode, a sensing circuit 150 may measure the voltage of a battery 200 through the second protruding portion 122.

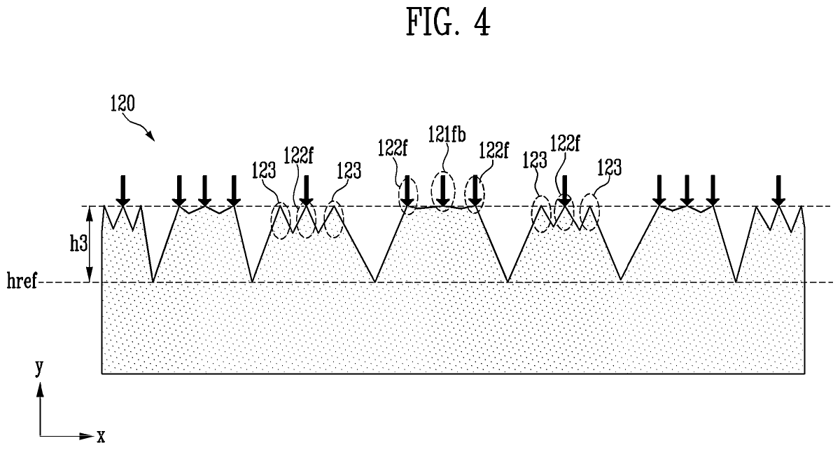

FIG. 4 shows a diagram for explaining a state in which a first protruding portion and a second protruding portion according to an embodiment are worn. FIG. 4 shows an enlarged diagram of a contact region 120 of FIG. 1.

Referring to FIGS. 1 and 4, in an embodiment, when a first protruding portion 121fb and a second protruding portion 122f are worn so that a first length of the first protruding portion 121fb and a second length of the second protruding portion 122f become less than or equal to a third length h3 of a third protruding portion 123, the third protruding portion 123 may be contacted with an opposing electrode.

Specifically, as a first protruding portion 121fb and a second protruding portion 122f are worn depending on the usage time or number of contacts with a battery measurement device 100, a first length of the first protruding portion 121fb and a second length of the second protruding portion 122f may become less than or equal to a third length h3 of a third protruding portion 123. In this state, the first electrode contact terminal 110a may be contacted with a first electrode 210a to measure the voltage of a battery 200. In this case, the third protruding portion 123 among the protruding portions 121fb, 122f, and 123 included in the first electrode contact terminal 110a may be contacted with the first electrode 210a.

In an embodiment, while a third protruding portion 123 is contacted with an opposite electrode, a sensing circuit 150 may measure the voltage of a battery 200 through the third protruding portion 123.

What is claimed is:

1. A battery measurement device comprising:
a first electrode contact terminal contacted with a first electrode of a battery to measure the voltage of the battery; and
a second electrode contact terminal contacted with a second electrode of the battery to measure the voltage;
wherein at least one of the first electrode contact terminal and the second electrode contact terminal includes: a first protruding portion protruding from a reference position to a first length to be contacted with an opposing electrode among the first electrode and the second electrode; and a second protruding portion protruding from the reference position to a second length to be contacted with the opposing electrode when the first protruding portion is worn.

2. The battery measurement device of claim 1, wherein, when the first length is formed to be longer than the second length, the first protruding portion is contacted with the opposing electrode.

3. The battery measurement device of claim 2, further comprising: a sensing circuit measuring the voltage of the battery through the first protruding portion while the first protruding portion is contacted with the opposing electrode.

4. The battery measurement device of claim 1, wherein the difference between the first length and the second length before the first protruding portion is worn is 500 μm or more.

5. The battery measurement device of claim 1, wherein, when the first protruding portion is worn and the first length is formed to be less than or equal to the second length, the second protruding portion is contacted with the opposing electrode.

6. The battery measurement device of claim 5, further comprising: a sensing circuit measuring the voltage of the battery through the second protruding portion while the second protruding portion is contacted with the opposing electrode.

7. The battery measurement device of claim 5, wherein at least one of the first electrode contact terminal and the second electrode contact terminal includes a third protruding portion protruding from the reference position to a third length to be contacted with the opposing electrode when the first protruding portion and the second protruding portion are worn.

8. The battery measurement device of claim 7, wherein, when the first protruding portion and the second protruding portion are worn and the first length and the second length are formed to be less than or equal to the third length, the third protruding portion is contacted with the opposing electrode.

9. The battery measurement device of claim 8, further comprising: a sensing circuit measuring the voltage of the battery through the third protruding portion while the third protruding portion is contacted with the opposing electrode.

10. The battery measurement device of claim 7, wherein the difference between the second length and the third length before the second protruding portion is worn is 500 μm or more.
